(19) United States
(12) Patent Application Publication
(10) Pub. No.: US 2026/0035796 A1
(43) Pub. Date: Feb. 5, 2026

(54) SUBSTRATE PROCESSING APPARATUS INCLUDING A SUPPORT MEMBER

(71) Applicant: SAMSUNG ELECTRONICS CO., LTD., SUWON-SI (KR)

(72) Inventors: Sunwoo BANG, Suwon-si (KR); Hyeong Un JEON, Suwon-si (KR); Yeontae KIM, Suwon-si (KR); Hyunseok KANG, Suwon-si (KR); Hyeonjin JEON, Suwon-si (KR)

(21) Appl. No.: 19/021,359

(22) Filed: Jan. 15, 2025

(30) Foreign Application Priority Data
Jul. 31, 2024 (KR) 10-2024-0101538

(51) Int. Cl. C23C 16/46; C23C 16/455; C23C 16/458

(52) U.S. Cl. CPC C23C 16/46; C23C 16/45557; C23C 16/4584

(57) ABSTRACT

A substrate processing apparatus including a process chamber, a substrate support disposed inside the process chamber, a heating unit configured to supply heat into the process chamber, and a plurality of support members detachably coupled to the substrate support. Each of the plurality of support members includes a body part extending in a first direction substantially perpendicular to an upper surface of the substrate support, and a plurality of support slots formed in the body part, each of the plurality of support slots configured to receive an insertion of a substrate, and to support the substrate and position the substrate with its length substantially in parallel to the upper surface of the substrate support.

### CROSS-REFERENCE TO RELATED APPLICATION

This U.S. non-provisional patent application claims priority under 35 U.S.C. § 119 to Korean Patent Application No. 10-2024-0101538, filed on Jul. 31, 2024, in the Korean Intellectual Property Office, the entire disclosure of which is incorporated by reference in its entirety.

### BACKGROUND

### 1. Technical Field

Embodiments of the present disclosure relate to a substrate processing apparatus. More

specifically, embodiments of the present disclosure relate to a substrate processing apparatus including a support member.

### 2. Discussion of Related Art

Semiconductor devices are formed by using various semiconductor manufacturing processes such as deposition processes, ion implantation processes, photolithography processes, or etching processes. The deposition process is a process of forming a thin film or material film on a substrate. In some cases, methods such as chemical vapor deposition (CVD), atomic layer deposition (ALD), etc. may be used during the deposition process.

In some cases, microwaves may be irradiated into the chamber of the substrate processing apparatus to facilitate deposition or annealing in the semiconductor device. In some cases, for example, dielectric loss and ohmic loss are generated as the electric and magnetic fields formed by the microwaves pass through the material, generating thermal energy within the processing chamber. To enhance the manufacturing efficiency of the semiconductor substrate processing apparatus, methods for performing processes on a plurality of wafers while improving the efficiency of the semiconductor manufacturing process are being researched and developed.

### SUMMARY

Embodiments of the present disclosure provide a substrate processing apparatus capable of enhancing the efficiency of a semiconductor manufacturing process. Embodiments of the present disclosure provide a substrate processing apparatus capable of simultaneously processing a plurality of substrates. Embodiments of the present disclosure provide a substrate processing apparatus capable of efficiently controlling the temperature of the substrate.

According to some embodiments of the present disclosure, a substrate processing apparatus may include a process chamber including a substrate, a substrate support disposed inside the process chamber, a plurality of support members detachably coupled to the substrate support and supporting the substrate, and a heating unit supplying microwaves into the process chamber to heat the substrate. In some aspects, the plurality of support members may include a body part extending in a first direction perpendicular to an upper surface of the substrate support, and a support slot formed in body part configured to receive an insertion of a portion of the substrate and support the substrate parallel to the upper surface of the substrate support.

According to some example embodiments of the present disclosure, a substrate processing apparatus may include a process chamber including a substrate, a gas supply unit supplying a process gas into the process chamber, a heating unit supplying microwaves into the process chamber to heat the substrate, a pedestal disposed in the process chamber, a baffle disposed around the pedestal to partition the process chamber into a processing space and an exhaust space, and a plurality of support members detachably coupled to the pedestal in a first direction perpendicular to an upper surface of the pedestal and supporting the substrate. In some aspects, the baffle includes an exhaust hole configured to discharge the process gas from the processing space to the exhaust space.

According to some example embodiments of the present disclosure, the substrate processing apparatus may include a process chamber including a substrate, a gas supply unit supplying a process gas into the process chamber, a heating unit supplying microwaves into the process chamber to heat the substrate, a pedestal connected to a support shaft disposed in the process chamber, a driving device connected to the support shaft and rotatably driving the pedestal, a baffle disposed around an outer circumference of the pedestal at a same level as the pedestal to partition the process chamber into a processing space and an exhaust space, a pump configured to discharge the process gas from the processing space to outside of the process chamber through the exhaust space, a first support member disposed at a first position on the pedestal in a first direction to support a first portion of the substrate, a second support member disposed at a second position on the pedestal, where the second position is spaced apart from the first position in a second direction perpendicular to the first direction to support a second portion of the substrate, and a third support member disposed at a third position on the pedestal, where the third position is between the first position and the second position. In some aspects, each of the first support member, the second support member, and the third support member may include a body part extending in the first direction, a plurality of support slots formed in a side of the body part to support the substrate, and a coupling part configured to couple one end of the body part to an insertion hole of the pedestal, and the baffle includes an exhaust hole configured to discharge the process gas from the processing space to the exhaust space.

### BRIEF DESCRIPTION OF THE DRAWINGS

FIG. 1 is a schematic diagram illustrating a substrate processing apparatus according to some embodiments of the present disclosure.

FIG. 2 is a cross-sectional view illustrating the substrate processing apparatus according to some embodiments of the present disclosure.

FIG. 3 is a perspective view illustrating a support member according to some embodiments of the present disclosure.

FIG. 4 is an exploded view illustrating a part of a configuration of the substrate processing apparatus according to some embodiments of the present disclosure.

FIG. 5 is a plan view illustrating a substrate and a support member according to some embodiments of the present disclosure.

FIGS. 6 and 7 are plan views illustrating the substrate inserted into the support member according to some embodiments of the present disclosure.

FIG. 8 is a graph illustrating the relationship between the intensity of microwaves and the temperature of the substrate with respect to the number of wafers according to some embodiments of the present disclosure.

FIGS. 9 and 10 are diagrams illustrating a part of the configuration of a substrate processing apparatus according to some embodiments of the present disclosure.

FIG. 11 is a cross-sectional view of the substrate processing apparatus according to some embodiments of the present disclosure.

FIG. 12 is a conceptual diagram illustrating the microwaves and exhaust holes of a baffle according to embodiments of the present disclosure.

FIGS. 13 and 14 are enlarged views of part A of FIG. 11 according to embodiments of the present disclosure.

### DETAILED DESCRIPTION

Hereinafter, a substrate processing apparatus according to some embodiments is described in detail with reference to the drawings. The same reference numerals are used for the same components in the drawings, and redundant descriptions of the same components may be omitted.

It will also be understood that when a layer is referred to as being “on” or “under” another layer or substrate, it can be directly on the other layer or substrate, or intervening layers may also be present. For example, when the disclosure describes a first layer disposed on a second layer, then the first layer may be directly disposed on the second layer. In some cases, for example, a third layer may be disposed between the first layer and the second layer. In some aspects, the same reference numbers indicate the same components throughout the specification.

It will be understood that, although the terms “first,” “second,” etc. may be used herein to describe various elements, these elements should not be limited by these terms. These terms are only used to distinguish one element from another element. For example, a first element discussed below could be termed a second element without departing from the teachings and spirit of the present disclosure. Similarly, the second element could also be termed the first element.

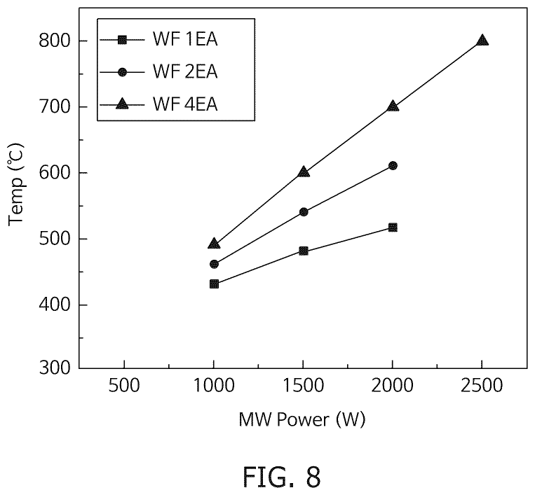

Embodiments of the present disclosure provide a substrate processing apparatus including a process chamber, a substrate support disposed in the process chamber, and a plurality of support members disposed on the substrate support, where the plurality of support members is configured to support one or more substrates. For example, the support member includes a body part, a coupling part, a locking part, and a plurality of support slots, the plurality of support slots are designed to stably support one or more substrates in the processing space of the process chamber. In some aspects, the plurality of support slots are spaced apart from each other by a predetermined distance. By disposing two or more substrates onto the corresponding support slots of the support member, a space is formed between a substrate and an adjacent substrate. Accordingly, the space may function as a heat storage, where heat generated by a heating unit of the substrate processing apparatus can be stored. Accordingly, the spacings between the plurality of support slots enables simultaneous processing of the substrates and increases the heating efficiency. Furthermore, as shown in FIG. 8, by heating multiple substrate wafers simultaneously, the base temperature of each wafer can reach a target temperature using less microwave energy, thus further improves the energy efficiency of the substrate processing apparatus.

In some aspects, the substrate processing apparatus further includes a baffle with a plurality of exhaust holes. For example, the baffle partitions the process chamber into a process space and an exhaust space. The substrate processing apparatus further includes a pump configured to discharge processing gap from the process chamber to the outside through the exhaust space. In one aspect, each of the plurality of exhaust holes may have a predetermined width. For example, the width of the exhaust hole is less than or equal to one-fourth of the wavelength of the microwave generated by the heating unit. Accordingly, baffle of the substrate processing apparatus can control the pressure within the processing space and prevent leakage of the microwaves through the exhaust holes.

According to some embodiments, microwaves applied to the process chamber of the semiconductor substrate processing apparatus heat the wafer substrates, thus providing a temperature range and environment in which process can proceed, thereby improving the efficiency of semiconductor manufacturing processes. According to some embodiments, a structure capable of simultaneously processing a plurality of substrates within the semiconductor substrate processing apparatus to increase the efficiency of heating by the microwaves is provided.

According to some embodiments, a baffle structure formed in the boundary area between the chamber and the exhaust structure in the semiconductor substrate processing apparatus to prevent leakage of the microwaves while exhausting the process gas and thereby maintaining a vacuum state is provided. Accordingly, in areas other than the process area in the substrate processing apparatus, the leakage of microwaves can be reduced.

According to some embodiments, the efficiency of heating by the microwaves can be increased by utilizing a structure that processes a plurality of substrates simultaneously in the semiconductor substrate processing apparatus and a baffle structure that shields microwaves and exhausts the process gas.

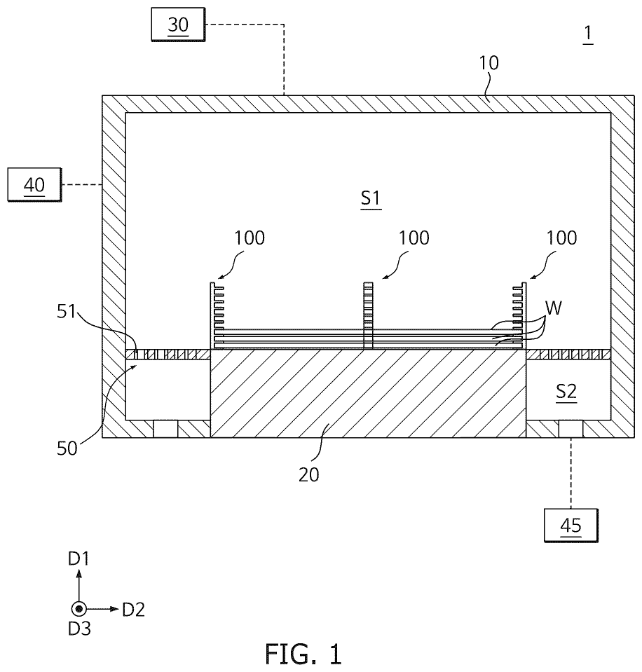

FIG. 1 is a schematic diagram illustrating a substrate processing apparatus according to some embodiments of the present disclosure. Referring to FIG. 1, a substrate processing apparatus 1 may include a process chamber 10, a substrate support 20, a heating unit 30, a gas supply unit 40, a baffle 50, and a support member 100.

The process chamber 10 may be provided for processing a substrate W. For example, the process chamber 10 includes a processing space S1 within the process chamber 10 where the substrate W is processed. The substrate W may be processed in the processing space S1 of the process chamber 10. In some cases, the method of processing the substrate W may include deposition process, photolithography process, etching process, annealing process, etc., but is not limited thereto. In some example embodiments, the substrate processing apparatus 1 may include an apparatus for single crystal epitaxy.

In some aspects, the process chamber 10 includes an exhaust space S2 for maintaining a vacuum state in the processing space S1. The processing space S1 and the exhaust space S2 may be partitioned by the baffle 50. For example, the processing space S1 and the exhaust space S2 may be partitioned by an upper surface (or upper portion) of the substrate support 20 and the baffle 50 disposed around the substrate support 20.

The inside of the process chamber 10 may be in a vacuum state. For example, the processing space S1 of the process chamber 10 may be in a vacuum state. However, example embodiments are not limited thereto, and both the processing space S1 and the exhaust space S2 may be in a vacuum state. The vacuum state used herein may also include a state of low pressure and does not necessarily refers to the complete absence of process gas.

A pump 45 may be disposed on one side of the process chamber 10 to maintain the vacuum state or adjust the pressure within the process chamber 10. The pump 45 may discharge the process gas from the exhaust space S2 to the outside of the process chamber 10.

The substrate support 20 may support the substrate W. For example, the substrate support 20 may be coupled with the support member 100 for supporting the substrate W. For example, the support member 100 is disposed on an upper surface of the substrate support 20. The support member 100 may be configured to support one or more substrates W (or a plurality of substrates W). The plurality of substrates W supported by the support member 100 may be spaced apart at predetermined gap from an upper surface of the substrate support 20. The substrates W may be supported parallel to the upper surface of the substrate support 20 by the support member 100.

The substrate support 20 may have an upper surface in the shape of a disc corresponding to the shape of the substrate W. In some cases, the substrate support 20 may include a rotation mechanism that may rotate the substrates W in the horizontal direction. In some cases, the substrate support 20 may include a lifting mechanism that may adjust a height of the substrates W. For example, the substrate support 20 may move in an upward direction or a downward direction along the first direction D1. In some embodiments, the substrate support 20 may include one of the rotation mechanism or the lifting mechanism. In some embodiments, the substrate support 20 may include the rotation mechanism and the lifting mechanism. In some embodiments, the substrate support 20 may be stationary.

The heating unit 30 may supply microwaves to the processing space S1 of the process chamber 10. The microwaves may be supplied to the substrates W disposed in the processing space S1. The microwaves may cause the silicon crystals within the substrate W to vibrate, as thus, generating heat. For example, dielectric loss and ohmic loss are generated as the electric and magnetic fields formed by the microwaves pass through the substrate W, generating thermal energy in the chamber. As described above, the microwaves may result in generation of heat in the substrate W, raising the temperature of the substrate W.

The gas supply unit 40 may supply the process gas into the process chamber 10. The process gas may include deposition gas, etching gas, etc. For example, the process gas may include N₂, Ar, He, Ne, O₂, H₂, etc, but are not limited thereto. In some embodiments, the gas supply unit 40 may include a gas supply source disposed outside the process chamber 10, a gas injection unit installed inside the process chamber 10, and a gas supply line connecting the gas supply source and the gas injection unit.

The baffle 50 may be disposed around the substrate support 20. The baffle 50 may be disposed around an outer circumference of the substrate support 20. For example, the baffle 50 may be disposed around an outer circumference of the upper surface of the substrate support 20. Accordingly, the baffle 50 may be disposed at the same level as the upper surface of the substrate support 20. In one example, the baffle 50 may be in the shape of a ring. The baffle 50 may partition the interior of the process chamber 10 into the processing space S1 where the substrate W is processed with the process gas, and the exhaust space S2 where the process gas is discharged. The baffle 50 may be configured to discharge reaction by-products generated during the process from the processing space S1 to the exhaust space S2 and to the outside.

Exhaust holes 51 may be formed in the baffle 50 and configured to allow the process gas to pass through, while blocking the microwaves. The exhaust holes 51 may be formed on at least a portion of the baffle 50. In some example embodiments, the exhaust holes 51 may be formed over the entire area along a circumference of the baffle 50, but are not limited thereto. The exhaust holes 51 may be configured to exhaust the process gas and to prevent leakage of microwaves. The baffle 50 may discharge the process gas from the processing space S1 to the exhaust space S2. The baffle 50 may prevent the leakage of microwaves from the processing space S1 into the exhaust space S2. The baffle 50 may maintain the vacuum state of the processing space S1 while allowing the presence of the microwaves, thereby generating a substrate processing atmosphere inside the processing space S1. In some cases, the baffle 50 may prevent microwave loss by preventing the microwaves from leaking from the processing space S1 into the exhaust space S2. For example, by concentrating the microwaves within the processing space S1 using the baffle 50, the processing efficiency of the substrate W may be improved.

The support member 100 may be detachably coupled to the substrate support 20. For example, the support member 100 may be attached to or detached from the substrate support 20. A plurality of support members 100 may be provided. At least one or more substrates W may be provided. The plurality of support members 100 may be coupled to the substrate support 20 to support the at least one or more substrates W spaced apart at predetermined gap from the upper surface of the substrate support 20. The substrates W may be supported by the support members 100 and disposed in the processing space S1. Each of the plurality of support members 100 may include a body part extending in a first direction D1, and a plurality of support slots formed in the body part, into which a portion of the substrate W is inserted so as to be supported parallel to the upper surface of the substrate support 20. The plurality of support slots may be formed on a side of the support member 100 in a second direction D2 intersecting the first direction D1. In some cases, each of the plurality of support slots of the support member 100 may be spaced apart by a predetermined distance from each other. Accordingly, each of the plurality of the substrates W may be also spaced apart by at least the same predetermined distance. By processing the plurality of substrates W simultaneously using the support members 100 detachably coupled to the substrate support 20, the heating efficiency by the microwaves may be increased. For example, the distance between each of the plurality of support slots of the support member 100 may be adjusted (uniformly or varyingly) to increase the heating efficiency by the microwaves generated from the heating unit 30.

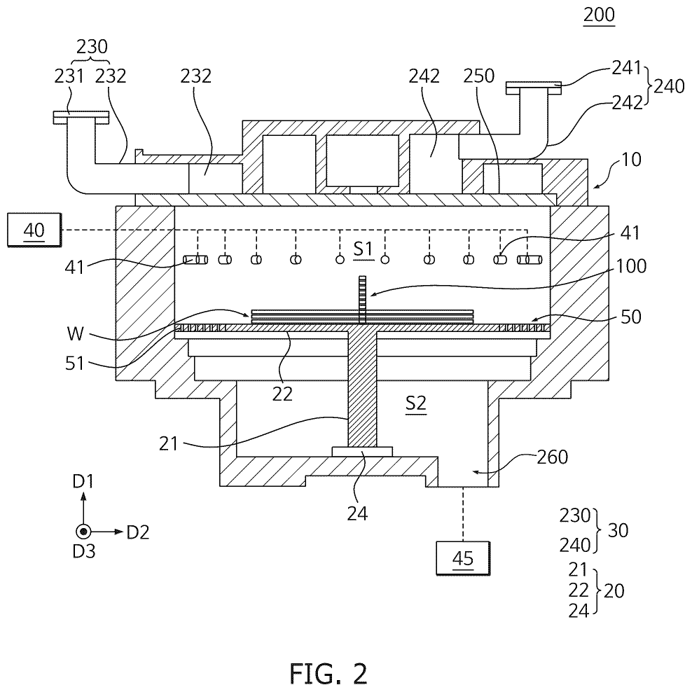

FIG. 2 is a cross-sectional view illustrating the substrate processing apparatus according to some embodiments of the present disclosure. Referring to FIG. 2, the substrate processing apparatus 200 may include the process chamber 10, the substrate support 20, the heating unit 30, the gas supply unit 40, the baffle 50, and the support member 100. Hereinafter, detailed descriptions of components that are the same or similar to those of the substrate processing apparatus 1 in FIG. 1 may be omitted, and the differences from those of the substrate processing apparatus 1 are further described in detail.

The process chamber 10 may be provided for processing the substrate W. The process chamber 10 may be formed in an approximately cylindrical shape, and may include, inside the process chamber 10, the processing space S1 where the substrate W is processed, and the exhaust space S2 for maintaining the vacuum state of the processing space S1. The processing space S1 and the exhaust space S2 may be partitioned by the upper surface (or upper portion) of the substrate support 20 and the baffle 50 disposed around the upper surface of the substrate support 20. For example, the processing space S1 and the exhaust space S2 may be partitioned by a pedestal 22 of the substrate support 20 and the baffle 50 disposed around the pedestal 22.

An inner wall of the process chamber 10 may be formed of various materials based on the substrate processing method. For example, the inner wall of the process chamber 10 may be formed of quartz to increase the heating efficiency of the microwaves and to facilitate cleaning. In another example, the inner wall of the process chamber 10 may be formed of a metallic material such as aluminum, an aluminum alloy, etc., allowing the microwaves to be reflected and directed toward the substrate W.

The heating unit 30 may be disposed above the process chamber 10 and may provide microwaves into the process chamber 10. As illustrated in FIG. 2, the heating unit 30 may include a plurality of microwave units (e.g., a first microwave unit 230 and second microwave unit 240). Each of the first microwave unit 230 and second microwave unit 240 may include a first microwave source 231 and second microwave source 241 and a first waveguide 232 and second waveguide 242, respectively. For example, the first microwave source 231 and second microwave source 241 generates microwaves. For example, a first waveguide 232 and second waveguide 242 delivers the microwaves into the process chamber 10. The first microwave source 231 and second microwave source 241 may be a magnetron with an anode and a cathode applied with a common voltage from a high-voltage supply to generate microwaves. The magnetron may generate microwaves of various frequencies based on the substrate processing method. The microwaves generated by the magnetron may have frequencies in the range of 2.5 GHz or higher, but example embodiments are not limited thereto.

The microwaves may be delivered into the process chamber 10 through the first waveguide 232 and second waveguide 242 jointly or separately. The first waveguide 232 and second waveguide 242 may have a tubular shape with a rectangular or elliptical cross-section. Inner surfaces of the first waveguide 232 and second waveguide 242 may include a conductor. In some embodiments, the inner surfaces of the first waveguide 232 and second waveguide 242 may include gold or silver.

The first waveguide 232 and second waveguide 242 may be disposed or may extend above an upper surface of the process chamber 10. Each of the first microwave source 231 and second microwave source 241 may be connected to one end of the first waveguide 232 and second waveguide 242. The other end of the first waveguide 232 and second waveguide 242 may be connected to an upper surface of a transmissive window 250 attached to an upper portion of the process chamber 10. The microwaves generated by the first microwave source 231 and second microwave source 241 may be supplied to the processing space S1 of the process chamber 10 through the first waveguide 232 and second waveguide 242 and the transmissive window 250.

For example, the first waveguide 232 of the first microwave unit 230 may be in the shape of a ring to pass through an outer circumference of an upper surface of the transmissive window 250. In some cases, the second waveguide 242 of the second microwave unit 240 may be in the shape of a ring to pass through an inner side of the outer circumference of the upper surface of the transmissive window 250. By appropriately arranging the first waveguide 232 and second waveguide 242 of the first microwave unit 230 and second microwave unit 240 on the upper surface of the transmissive window 250, microwaves may be irradiated substantially uniformly to all sides of the substrate W in the processing space S1 of the process chamber 10.

In some embodiments, the first microwave source 231 of the first microwave unit 230 and the second microwave source 241 of the second microwave unit 240 may generate microwaves having different frequencies. In some cases, the first microwave source 231 and the second microwave source 241 may generate microwaves having the same frequencies. In some embodiments, the substrate processing apparatus 200 includes a first microwave unit 230 including a first microwave source 231 and a plurality of first waveguides 232 disposed on an upper portion of the process chamber 10.

The transmissive window 250 may be formed of a dielectric material. The material of the transmissive window 250 may include, for example, quartz, ceramics, etc. The transmissive window 250 may be hermetically connected to the upper portion of the process chamber 10 using a sealing member, etc. A distance from a lower surface of the transmissive window 250 to the surface of the substrate W or to an upper surface of the pedestal 22 may be appropriately set based on the heating efficiency of the microwaves, etc.

The gas supply unit 40 may supply the process gas into the process chamber 10. The gas supply unit 40 may include a gas supply source, a gas injection unit 41, and a gas supply line connecting the gas supply source and the gas injection unit 41. The gas injection unit 41 may include a plurality of injection nozzles installed at predetermined spacings along an inner circumference of the process chamber 10. For example, the gas injection unit 41 may be disposed on a sidewall of the process chamber 10.

The pump 45 may be disposed on one side of the exhaust space S2 of the process chamber 10 to maintain the vacuum state or adjust the pressure within the process chamber 10. The pump 45 may discharge the process gas to the outside of the process chamber 10 through an exhaust port 260 of the exhaust space S2. For example, the pump may be a vacuum pump such as a dry pump.

In some aspects, the substrate support 20 includes a support shaft 21, a pedestal 22, and a driving device 24. The substrate support 20 may support the substrate W. For example, the pedestal 22 of the substrate support 20 may be coupled with the support member 100 for supporting the substrate W. The support member 100 may support the plurality of substrates W. The substrates W supported by the support member 100 may be spaced apart at predetermined distance from an upper surface (or a first side) of the pedestal 22. The substrate W may be supported by the support member 100 parallel to the upper surface of the pedestal 22. In some cases, a portion of the pedestal 22 may be formed of quartz. For example, the upper surface of the pedestal 22 may be formed of quartz.

A support shaft 21 may be connected to a lower surface (or a second side) of the pedestal 22 perpendicularly to the lower surface of the pedestal 22. For example, the pedestal 22 may be in the shape of a disc, but is not limited thereto. The pedestal 22 may be rotated around a rotation axis of the support shaft 21 around the first direction D1. In some embodiments, the support shaft 21 may be coupled to a driving device 24. The support shaft 21 may be integrally formed with the driving device 24. The driving device 24 may include a drive motor that generates rotational force. The drive motor may be a brushless direct-current BLDC motor, an actuator, and/or a hydraulic motor. In some example embodiments, the support shaft 21 and the driving device 24 may be disposed in the exhaust space S2 of the process chamber 10.

The driving device 24 may be connected to the support shaft 21 to rotatably drive the pedestal 22. The driving device 24 may transmit the rotational force to the pedestal 22 through the support shaft 21. The driving device 24 may rotate the pedestal 22 in a clockwise or counterclockwise direction when viewed from a top view. The driving device 24 may adjust a rotation speed of the pedestal 22 using a control unit. The driving device 24 may adjust the rotation speed differently. As the pedestal 22 is rotated, the support member 100 attached to the pedestal 22 and the substrate W may also be rotated together. Because the substrate W is rotatable during the substrate processing performed by the substrate processing apparatus 200, the limitations on the installation position of the gas injection unit 41 and pump 45 within the substrate processing apparatus 1 may be reduced.

The support member 100 may be detachably coupled to the pedestal 22. For example, the support member 100 may be attached to or detached from the pedestal 22. A plurality of support members 100 may be provided. At least one or more substrates W may be provided. The plurality of support members 100 may be coupled to the pedestal 22 to support at least one substrate W spaced apart from the upper surface of the pedestal 22 at a predetermined distance. The substrates W may be supported by the support members 100 and disposed in the processing space S1. Processing such as thin-film deposition may be performed on the substrate W which is rotated by the rotation of the pedestal 22.

The baffle 50 may be disposed around an outer circumference of the pedestal 22 at the same level as the pedestal 22. In one example, the baffle 50 may be in the shape of a ring. The exhaust holes 51 may be formed in the baffle 50 and configured to enable the process gas to pass through while preventing the passage of the microwaves from the processing space S1 to the exhaust space S2 of the process chamber 10. The exhaust holes 51 may be formed on at least a portion of the baffle 50. In some example embodiments, the exhaust holes 51 may be formed over the entire area along the circumference of the baffle 50, but are not limited thereto. For example, the baffle 50 may include an inner ring surrounding the pedestal 22, an outer ring spaced apart from the inner ring in an outward direction, and a plurality of exhaust holes 51 disposed between the inner and outer rings. In some cases, the outer ring of the baffle 50 may be disposed on the inner sidewall of the process chamber 10. The exhaust holes 51 may be configured to exhaust the process gas while preventing leakage of microwaves. The baffle 50 may discharge the process gas from the processing space S1 to the exhaust space S2. The baffle 50 may prevent the microwaves from leaking from the processing space S1 into the exhaust space S2 of the process chamber 10.

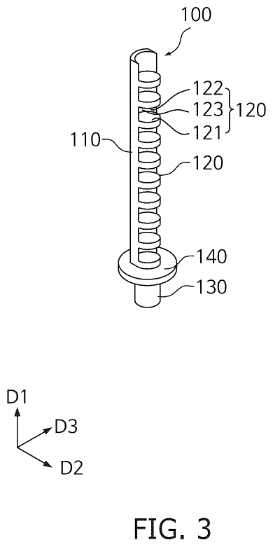

Hereinafter, the support member 100 for supporting the substrate W, and the baffle 50 are described in detail. FIG. 3 is a perspective view illustrating a support member according to some embodiments of the present disclosure.

As shown in FIG. 3, the support member 100 in the substrate processing apparatus may be detachably coupled to the substrate support and may include a plurality of support slots 120 formed in a body part 110 to support at least one substrate. For example, the support member 100 may include the body part 110, the support slots 120, a coupling part 130, and a locking part 140. In an embodiment, the support slot 120 includes a support surface 121, an opposite surface 122, and a slot surface 123. The support member 100 may be made of a material that is resistant to heat generated by the microwave in the substrate processing apparatus and favorable for cleaning processes. For example, the support member 100 may be formed of quartz, but is not limited thereto.

The body part 110 may extend in the first direction D1. For example, if the body part 110 is coupled to the upper surface of the substrate support, the body part 110 may be configured to extend in the height direction of the substrate support. One end of the body part 110 in the first direction D1 may be connected with the coupling part 130. The body part 110 and the coupling part 130 may be divided by the locking part 140.

The support slots 120 may be formed on the body part 110. The support slots 120 may be formed as portions of the body part 110 that are recessed in a second direction D2 or third direction D3 intersecting the first direction D1 and the second direction D2. The support slots 120 may be formed after the cylindrical body part 110 is formed, by cutting or machining at least a portion of a side surface of the body part 110, or the support slots 120 may be integrally formed on the side surface of the body part 110 through a molding process.

The support member 100 may include a support surface 121 forming the support slot 120, an opposite surface 122 facing the support surface 121, and a slot surface 123 connecting the support surface 121 and the opposite surface 122. For example, the slot surface 123 is perpendicular to each of the support surface 121 and the opposite surface 122. The substrate may be supported on the support surface 121. The support surface 121 and the opposite surface 122 may be the same or substantial similar in shape. A distance between the support surface 121 and the opposite surface 122 may correspond to a width (or height measured in the first direction D1) of the slot surface 123, that is, to a width of the support slot 120 measured in the first direction D1. The distance between the support surface 121 and the opposite surface 122 may be equal to or greater than a thickness of the substrate.

A plurality of support slots 120 may be provided on the side surface of the body part 110. Each of the plurality of support slots 120 may support the substrate W. A portion or an outer circumference of the substrate W may be inserted into the support slot 120. For example, the support slot 120 may support one side of the substrate W.

The plurality of support slots 120 may be spaced apart from each other by a predetermined distance along an extension direction (e.g., the first direction) of the body part 110. For example, the plurality of support slots 120 may be spaced apart from each other at a predetermined distance along the first direction D1. Distances between the substrates W supported by the plurality of support slots 120 may be adjusted as needed. In some embodiments, the plurality of support slots 120 may be spaced apart from each other at different distances. For example, a distance between each of the plurality of support slots 120 along the extension direction of the body part 110 may vary. In some cases, the distance between each of the plurality of the support slots 120 may be determined based on the number of substrates, the frequency of the microwave, etc. to increase the heating efficiency as a result of the microwave generated by the heating unit 30 as shown in FIGS. 1 and 2.

Each of the plurality of support slots 120 may have a certain width along the extension direction of the body part 110. For example, the width of the support slot 120 may be greater than or equal to the thickness of the substrate W. However, example embodiments are not limited thereto, and the width of the support slot 120 may be substantially the same as the thickness of the substrate W.

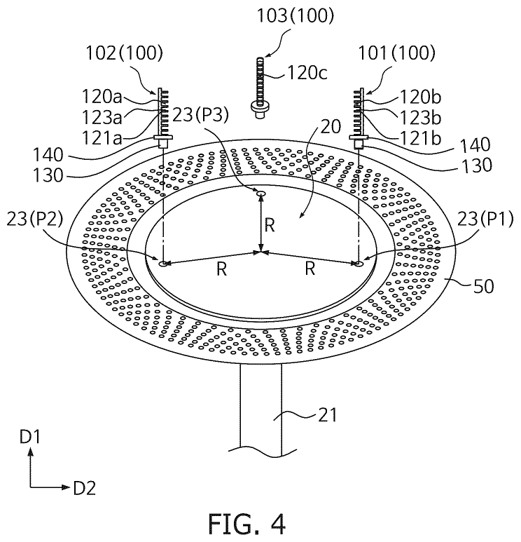

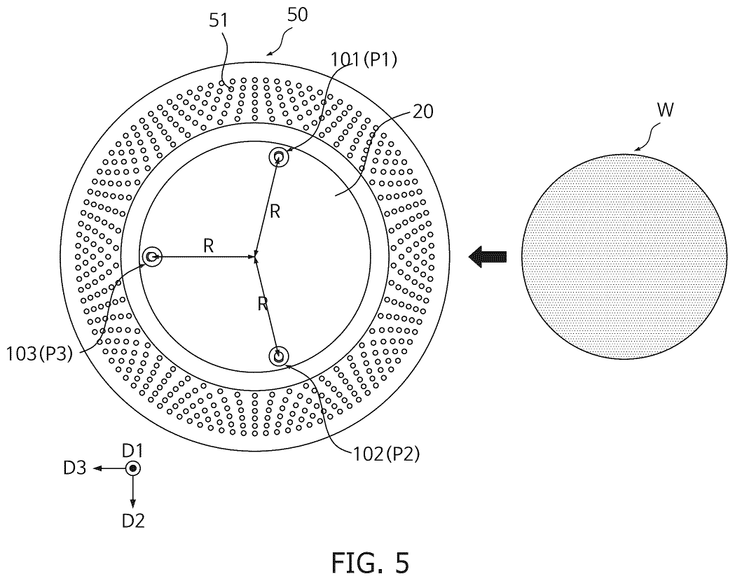

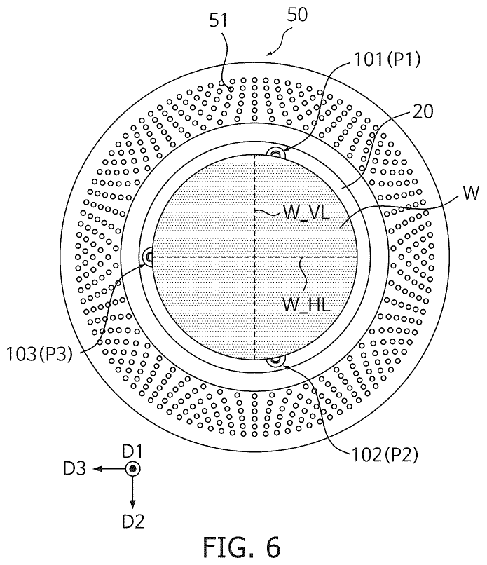

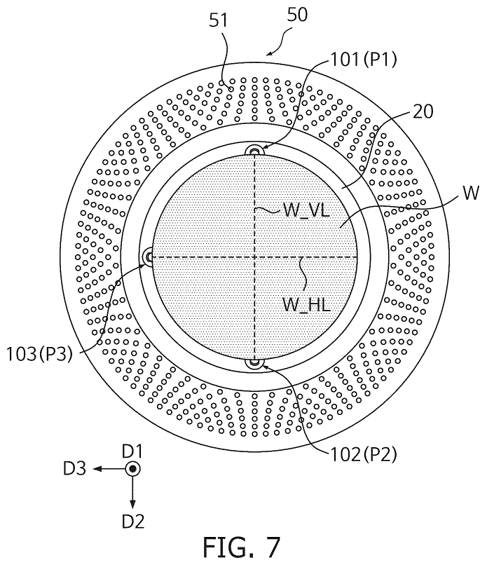

FIG. 4 is an exploded view illustrating a part of a configuration of the substrate processing apparatus according to some embodiments of the present disclosure. FIG. 5 is a plan view illustrating a substrate and the support member according to some embodiments of the present disclosure. FIGS. 6 and 7 are plan views illustrating the substrate inserted into the support member according to some embodiments of the present disclosure.

Referring to FIG. 4, the coupling part 130 of the support member 100 may be formed to be coupled to the substrate support 20 or the pedestal 22. In some embodiments, the coupling part 130 may be formed to be inserted into the substrate support 20. The coupling part 130 may have the shape of a cylindrical bar with a predetermined length. The substrate support 20 or the pedestal 22 may include an insertion hole 23 corresponding to the coupling part 130 of the support member 100 to receive the coupling part 130 of the support member 100 inserted therein. The insertion hole 23 may have an approximately cylindrical shape. However, the shapes of the coupling part 130 and the insertion hole 23 are not limited to the above and the coupling part 130 and the insertion hole 23 may be formed in various shapes such as rectangular pillars and corresponding holes, elliptical pillars and corresponding holes, etc. In some embodiments, the coupling part 130 and the insertion hole 23 may have a separate coupling structure. For example, a coupling protrusion may be formed on the coupling part 130, and a coupling groove may be formed in the insertion hole 23 for coupling with the coupling part 130. However, this is merely one example, and the coupling part 130 and the insertion hole 23 may also be coupled through a fastening member, etc.

The locking part 140 may be disposed between the body part 110 and the coupling part 130. The locking part 140 may be a portion that is in contact with a portion of the upper surface of the substrate support 20 while the coupling part 130 is inserted in the insertion hole 23 of the substrate support 20. The locking part 140 may constrain the support member 100 from moving in the direction of coupling with the substrate support 20. For example, the locking part 140 may be a portion that supports the support member 100 so that the coupling part 130 is inserted into the substrate support 20. In some cases, the width of the locking part 140 measured in the second direction D2 is greater than the width of the coupling part 130 measured in the second direction D2 or the width of the insertion hole 23 measured in the second direction D2.

Hereinafter, the first direction D1 may be a direction perpendicular to or intersecting the upper surface of the substrate support 20, and the second direction D2 may be a direction parallel to the upper surface of the substrate support 20. The third direction D3 may be a direction perpendicular to or intersecting the first direction D1 and the second direction D2. For example, the second direction D2 and the third direction D3 may be directions parallel to the upper surface of the substrate support 20.

The plurality of support members 100 may be coupled to the substrate support 20. Each of the plurality of support members 100 may be formed to be coupled to the substrate support 20. The plurality of support members 100 may include a first support member 101 coupled to a first position P1 on the substrate support 20, a second support member 102 coupled to a second position P2 on the substrate support 20, and a third support member 103 coupled to a third position P3 on the substrate support 20. The plurality of support members 100 may be detachably coupled to the substrate support 20 in the first direction D1 perpendicular to the upper surface of the substrate support 20.

Referring to FIGS. 4 to 7, the first position P1, the second position P2, and the third position P3 each corresponding to one of the three insertion holes 23 may be disposed on the same circumference of the upper surface of the substrate support 20. For example, the first position P1, the second position P2, and the third position P3 may be located on one circle, where the circle is the same center of the upper surface of the substrate support 20. Each of the first position P1, the second position P2, and the third position P3 may be equidistant from the center of the upper surface of the substrate support 20. For example, the first position P1, the second position P2, and the third position P3 may be spaced apart from the center of the upper surface of the substrate support 20 by a predetermined radius R.

For convenience of explanation, an imaginary line extending in the second direction D2 past the center of the substrate W is referred to as a vertical line W_VL, and an imaginary line extending in the third direction D3 past the center of the substrate W is referred to as a horizontal line W_HL. In some cases, intersection of the vertical line W_VL and the horizontal line W_HL may coincide with the center of the substrate W. For example, the vertical line W_VL and the horizontal line W_HL may may cross each other at the center of the substrate W or the center of the substrate support 20.

In the example shown in FIG. 6, the second position P2 may be located at a distance from the first position P1 in the second direction D2 that is perpendicular to or intersecting the first direction D1. For example, the first support member 101 may support a first side of the substrate W, and the second support member 102 may support a second side of the substrate spaced apart from the first side of the substrate W in the second direction D2. The third position P3 may be a position deviated from a straight line connecting the first position P1 and the second position P2. For example, the first position P1, the second position P2, and the third position P3 may form vertices of a triangle on the substrate support 20. The first position P1, the second position P2 and the third position P3 may be at different locations based on the vertical line W_VL or the horizontal line W_HL. In some embodiments, with respect to the center of the substrate support 20, each two of the plurality of insertion holes 23 (or the plurality of positions, P1, P2, and P3) may be equiangular with one another. For example, the angle between the first position P1 and the second position P2 may be 120 degrees, the angle between the second position P2 and the third position P3 may be 120 degrees, and the angle between the third position P3 and the first position P1 may be 120 degrees. Therefore, the plurality of support members 100 may support the substrate W more stably. However, embodiments of the present disclosure are not necessarily limited thereto. For example, the angles between each two positions (or two insertion holes) of the plurality of positions may be different.

In the example shown in FIG. 7, the second position P2 at which the second support member 102 is coupled to the substrate support 20 may be spaced apart from the first position P1 at which the first support member 101 is coupled by a width or diameter of the substrate W in the second direction D2. The first position P1 and the second position P2 may be located on the vertical line W_VL. In some cases, the third position P3 may be located on the horizontal line W_HL. Based on the center of the upper surface of the substrate support 20, the first position P1 and the second position P2 may be at a 90-degree interval from the third position P3. The third position P3 may be at a 90-degree interval from each of the first position P1 and the second position P2 based on the center of the upper surface of the substrate support 20. For example, the angle between the first position P1 and the third position P3 may be 90 degrees, the angle between the third position P3 and the second position P2 may be 90 degrees, and the angle between the second position P2 and the first position P1 may be 180 degrees.

The third support member 103, together with the first support member 101 and the second support member 102, may support the substrate W on the substrate support 20. The center of the substrate W supported by the plurality of support members 100 may coincide with the center of the upper surface of the substrate support 20. For example, the center of the substrate W and the center of the upper surface of the substrate support 20 may be on the same straight axis in the first direction D1. The center of the substrate W and the center of the upper surface of the substrate support 20 may be on the same axis as the support shaft 21 connected to the pedestal 22.

Because the first support member 101, the second support member 102, and the third support member 103 each support different three portions of the substrate W, the substrate processing apparatus may stably support the substrate W. In some embodiments, for the plurality of support members 100, three or more support members 100 may be provided.

In some embodiments, the substrate W may be supported by three or more support members 100 disposed on a circumference that is concentric with the center of the substrate support 20. The substrate W may be a semiconductor wafer in the shape of a disc, but is not limited thereto. For example, the substrate W may be supported by three or more support members 100 disposed in any shape such as polygon, ellipse, etc. on the substrate support 20.

The plurality of support slots 120 may be formed in each of the plurality of support members 100. For example, the plurality of support members 100 may support the plurality of substrates W. The plurality of support members 100 may include the first support member 101, the second support member 102, and the third support member 103. For convenience of description, the movement of the substrates is described with reference to one substrate W. The substrate W may be moved by a transfer robot. If there are a plurality of substrates W, the substrates W may be moved at once or the substrates W may be sequentially moved.

The first support member 101 and the second support member 102 may be spaced apart along the second direction D2, and the substrate W may be moved in the third direction D3 perpendicular to the first direction D1 and the second direction D2. The substrate W may be moved in between the first support member 101 and the second support member 102 to be inserted into a support slot 120a formed in the first support member 101 and to a support slot 120b formed in the second support member 102. The support slot 120a formed in the first support member 101 and the support slot 120b formed in the second support member 102 may be disposed on the same level. The first support member 101 and the second support member 102 may be spaced apart by a distance equal to or greater than the diameter of the substrate W so as not to interfere with the substrate W. For example, a distance between a slot surface 123a of the first support member 101 and a slot surface 123b of the second support member 102 may be greater than the diameter of the substrate W. In some cases, a distance between an end of a support surface 121a of the first support member 101 and an end of a support surface 121b of the second support member 102 may be less than the diameter of the substrate W. Accordingly, the substrate W can be stably disposed on support surface 121a of the first support member 101 and the support surface 121b of the second support member 102.

The substrate W may be supported by the support slot 120a formed in the first support member 101, the support slot 120b formed in the second support member 102, and a support slot 120c of the third support member 103. The third support member 103 may be disposed so that the substrate W moving in the third direction D3 is supported in the correct position. For example, the first support member 101, the second support member 102, and the third support member 103 may support the substrate W such that the center of the substrate W is on the same axis as the center of the upper surface of the substrate support 20 along the first direction D1.

The substrate W may be disposed on and spaced apart from the upper surface of the substrate support 20 in the first direction D1. For example, the substrate W may be spaced apart in the upward direction by the plurality of support members 100. With the substrate W supported by the plurality of support members 100 configured as described above, the substrate processing apparatus may process both the upper and lower surfaces of the substrate W. Because the plurality of substrates W are spaced apart in the first direction D1, both the upper and lower surfaces of the plurality of substrates W may be processed. For example, the plurality of substrates W may be processed simultaneously in a single processing space, improving process efficiency.

In some cases, because the plurality of substrates W are spaced apart in the vertical direction, the efficiency of heating by the microwaves may be enhanced. For example, each substrate W and an adjacent substrate W (in the vertical direction) may form a space where heat may be stored in the space. For example, each pair of substrates W may provide a certain amount of heat capacity in the space between the pair of substrates W. In some cases, heat may be generated as each of the substrates is heated, and the generated heat may be transferred between the substrates W. For example, the heat generated in each of the substrates W may be transferred to another substrate W by convection, radiation, etc.

FIG. 8 is a graph illustrating the relationship between the intensity of microwaves and the temperature of the substrate with respect to the number of wafers according to some embodiments of the present disclosure.

Referring to FIG. 8, the graph demonstrates that the substrate processing apparatus improves the heating efficiency by processing multiple wafers WF. For example, the graph in FIG. 8 illustrates the results of experiment conducted with a wafer as an example of the substrate. The graph in FIG. 8 illustrates the relationship between the intensity of microwaves and the temperature of the wafer WF based on the number of wafers. The x-axis of the graph represents the microwave power W, and the y-axis represents the temperature ° C. of the wafer. The graph illustrates the temperature change of the wafers WF based on the change in microwave power in cases where the number of wafers is 1, 2, and 4 is used.

For example, when one wafer WF is used to conduct the experiment, the base temperature is the lowest, and the temperature rise of the substrate with respect to the increase in microwave power is the lowest. On the contrary, as the number of wafers WF increases (for example, as more wafers WF are stacked on and spaced apart from each other using the substrate processing apparatus of the present disclosure), the base temperature increases, and the effect of the temperature rise of the wafers WF due to the increase in microwave power is also significantly increased. In some cases, for example, to reach a base temperature of 500°° C., a total of 2000 W of microwave power may be applied to a single wafer WF. However, by using the substrate processing apparatus, which simultaneously processes multiple wafers WF, a total of 1000 W of microwave power may be applied to the plurality of wafers WF, where each of the plurality of wafers WF can reach a base temperature of 500° C. Accordingly, the heating efficiency of the semiconductor manufacturing process is improved using the substrate processing apparatus of the present disclosure.

As described above, in the substrate processing apparatus, heat is generated as the plurality of substrates supported by the plurality of support members installed on the substrate support are heated, and transferred between the substrates. In some cases, the heat generated in each of the substrates may be transferred to another substrate by convection, radiation, etc. Therefore, as the number of wafers WF increases, the width of temperature rise of the wafers WF due to the change in microwave energy may increase. For example, the wafers WF may be heated more rapidly (e.g., rapid heating and cooling), thereby improving the efficiency of the semiconductor manufacturing process. In some cases, by applying the same range of microwave energy (e.g., 1000 W to 2000 W) to the different number of wafers, the temperature change of the wafers is different. For example, as shown in FIG. 8, when applying the same range of microwave energy to a single wafer WF, the temperature change is approximately less than 100° C. For example, when applying the same range of microwave energy to four wafers WF, the temperature change is approximately 200° C. Accordingly, by using the substrate processing apparatus, less microwave energy can be used for a wafer to reach a target temperature.

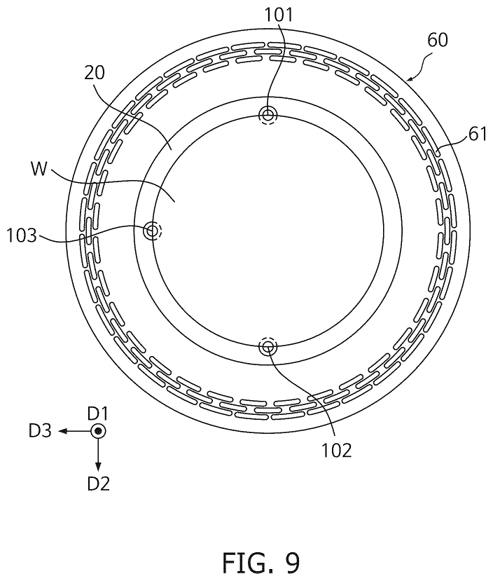

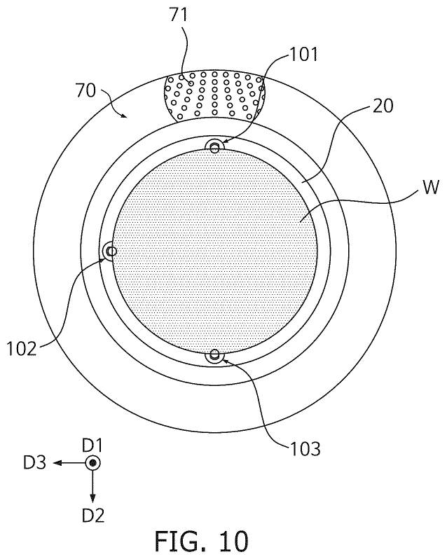

FIGS. 9 and 10 are diagrams illustrating a part of the configuration of a substrate processing apparatus according to some embodiments of the present disclosure. Referring to FIG. 9, a baffle 60 may include exhaust holes 61 in the form of a slit. The exhaust hole 61 may be in the shape of a slit with a major axis and a minor axis. The exhaust hole 61 may exhaust the process gas and prevent leakage of microwaves.

The exhaust holes 61 may be disposed along the circumference of the baffle 60. The exhaust holes 61 may be formed on at least part of the baffle 60. The exhaust holes 61 may be formed at a region adjacent to an outer circumference of the baffle 60. However, example embodiments are not limited to the above, and the exhaust holes 61 may be formed over the entire area of the baffle 60.

Referring to FIG. 10, a baffle 70 may include exhaust holes 71 formed on a partial region of the baffle 70. For example, the exhaust holes 71 may be formed on a portion of the baffle 70. The exhaust holes 71 in a circular shape are illustrated, but example embodiments are not limited thereto. For example, the exhaust hole 71 may be in the shape of a slit. The exhaust holes 71 may be provided in various forms or shapes, where the exhaust holes 71 are formed on a partial region of the baffle 70 to exhaust the process gas and prevent leakage of microwaves.

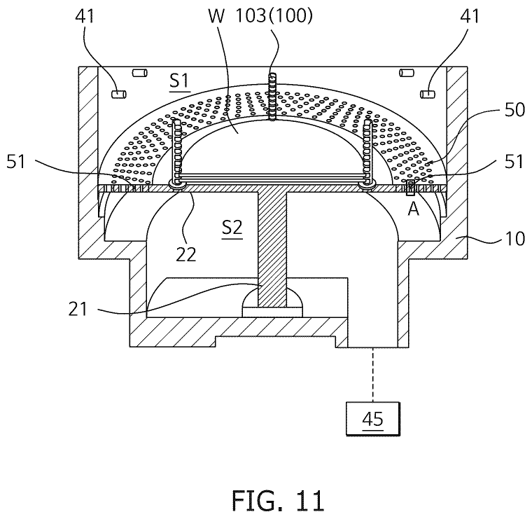

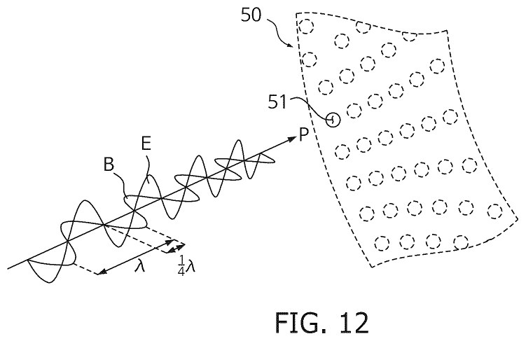

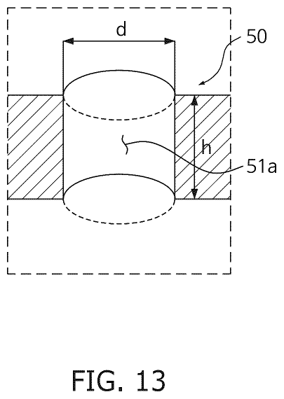

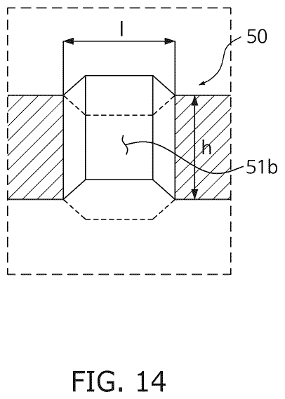

FIG. 11 is a cross-sectional view of the substrate processing apparatus according to some example embodiments. FIG. 12 is a conceptual diagram illustrating the microwaves and exhaust holes of a baffle according to some embodiments of the present disclosure. FIGS. 13 and 14 are enlarged views of part A of FIG. 11 according to some embodiments of the present disclosure.

Referring to FIGS. 11 to 14, the exhaust holes 51 may be formed on the baffle 50. The exhaust holes 51 of the baffle 50 enable the process gas to pass through, while blocking the microwaves from leaking. The baffle 50 may be disposed around the outer circumference of the substrate support 20 or the pedestal 22 to partition the processing space S1 and the exhaust space S2. The process gas may move between the processing space S1 and the exhaust space S2 through the exhaust holes 51. In some cases, to maintain the vacuum state or the low-pressure state of the processing space S1, the pump 45 may discharge the process gas inside the processing space S1 to the outside of the process chamber 10 through the exhaust space S2. Hereinafter, the conditions for the exhaust holes to discharge the process gas and prevent microwave loss are further describes described.

Referring to FIGS. 13 and 14, the exhaust hole 51 may be in the shape of a pillar with a predetermined height. For example, the exhaust hole 51 may have a height along the first direction D1 and may have a cross-sectional shape (e.g., circular, polygonal, etc.) cut along a direction perpendicular to or intersecting the first direction D1. The exhaust hole 51 may have a width d of a first length and a height h of a second length.

As illustrated in FIG. 12, microwaves may have a wavelength λ of a predetermined length along a propagation direction P. Electric field E and magnetic field B that make up the microwaves may be perpendicular to the propagation direction P and may travel along the propagation direction P. The first length of the width of the exhaust hole 51 may be less than or equal to one-fourth of the wavelength λ of the microwaves. For example, if the wavelength of the microwaves supplied from the heating unit is 12 cm, the first length of the width of the exhaust hole 51 may be less than or equal to 3 cm. In some cases, a ratio of the second length to the first length may be at least 1:1. For example, the second length may be greater than the first length. For example, the first length may be less than the second length. For example, the second length may be greater than or equal to 3 cm.

In some embodiments, the exhaust hole (61 in FIG. 9) may be in the shape of a slit with a major axis and a minor axis. If the major axis length of the exhaust hole 61 is less than or equal to one-fourth of the wavelength λ of the microwaves, microwaves may not pass through the slit-shaped exhaust hole 61.

As illustrated in FIG. 13, the exhaust hole 51a may have a cylindrical shape. For example, the exhaust hole 51a may have a circular cross-section cut along a direction perpendicular to or intersecting the first direction D1. Therefore, the width of the first length of the exhaust hole 51a may be a diameter d of the circle. In some cases, a height of a second length l2 of the exhaust hole 51a may be a height h of the cylinder.

The first length (or diameter d) of the exhaust hole 51a may be one-fourth of the wavelength λ of the microwaves supplied from the heating unit. For example, the diameter d of the cross-section of the exhaust hole 51a may be one-fourth of the wavelength λ of the microwaves. The second length (or height h) of the exhaust hole 51a may be greater than the first length of the exhaust hole 51a. Therefore, the diameter d of the cross-section of the exhaust hole 51a may be less than or equal to one-fourth of the wavelength λ of the microwaves and less than or equal to the height h of the exhaust hole 51a.

As illustrated in FIG. 14, the exhaust hole 51b may be in the shape of a regular polygonal pillar. For example, the exhaust hole 51b may be in the shape of a regular hexagonal pillar. However, this is merely one example, and cross-section of the exhaust hole 51b may be formed in other shapes such as square, regular octagon, etc. For example, the cross-section of the exhaust hole 51a cut along a direction perpendicular to the first direction D1 may have a regular polygonal shape. Therefore, the width of the first length of the exhaust hole 51a may be the length l of the diagonal (or a maximum width) of the regular polygon. In some cases, the height of the second length l2 of the exhaust hole 51a may be the height h of the regular polygonal pillar.

The first length of the exhaust hole 51b may be one-fourth of the wavelength λ of the microwaves supplied from the heating unit. For example, the length l of the cross-section of the exhaust hole 51b may be equal to or less than one-fourth of the wavelength λ of the microwaves. The second length of the exhaust hole 51b may be greater than or equal to the first length of the exhaust hole 51b. Therefore, the length l of the diagonal of the regular polygon of the cross-section of the exhaust hole 51b may be less than or equal to one-fourth of the wavelength λ of the microwaves and less than or equal to the height h of the exhaust hole 51b.

In some embodiments, the exhaust hole may be in the shape of a slit with a major axis and a minor axis. The length of the major axis of the slit-shaped exhaust hole may be less than or equal to one-fourth of the wavelength λ of the microwaves and less than or equal to the height of the slit-shaped exhaust hole.

Although the present disclosure has been described above by way of certain example embodiments and drawings, the present disclosure is not limited thereto, and it goes without saying that various changes and modifications can be made within the equivalent scope of the technical idea of the present disclosure and the claims to be described below by those of ordinary skill in the art.

1. A substrate processing apparatus, comprising:
a process chamber;
a substrate support disposed inside the process chamber;
a heating unit configured to supply heat into the process chamber; and
a plurality of support members detachably coupled to the substrate support, wherein each of the plurality of support members includes:
a body part extending in a first direction substantially perpendicular to an upper surface of the substrate support; and
a plurality of support slots formed in the body part, each of the plurality of support slots configured to receive an insertion of a substrate, and to support the substrate and position the substrate with its length substantially in parallel to the upper surface of the substrate support.

2. The substrate processing apparatus of claim 1, wherein:
the plurality of support slots are spaced apart from each other at a predetermined gap along the first direction.

1. The substrate processing apparatus of claim 1, wherein each of the plurality of support members further comprises:
a coupling part configured to couple the body part to an insertion hole of the upper
surface of the substrate support.

4. The substrate processing apparatus of claim 1, wherein the plurality of support members further comprises:
a first support member coupled to a first position on the upper surface of the substrate support; and
a second support member coupled to a second position on the upper surface of the substrate support, where the second position is spaced apart from the first position in a second direction perpendicular to the first direction.

5. The substrate processing apparatus of claim 4, wherein the plurality of support members further comprises:
a third support member coupled to a third position on the upper surface of the substrate support between the first position and the second position.

6. The substrate processing apparatus of claim 5, wherein:
the first position, the second position, and the third position are disposed on a same circumference having a center as the center of the upper surface of the substrate support, and
the third position forms a 90-degree angle with respect to each of the first position and the second position.

7. The substrate processing apparatus of claim 1, further comprising:
a gas supply unit supplying a process gas into the process chamber; and
a baffle formed with an exhaust hole configured to discharge the process gas.

8. The substrate processing apparatus of claim 7, wherein:
the exhaust hole is formed on at least a portion of the baffle.

9. The substrate processing apparatus of claim 7, wherein:
the exhaust hole has a width equal to or less than one-fourth of a wavelength of microwaves supplied from the heating unit.

10. The substrate processing apparatus of claim 9, wherein:
the exhaust hole has a height greater than or equal to the width.

11. The substrate processing apparatus of claim 7, wherein:
the exhaust hole has a cross-section of a circular or polygonal shape.

12. The substrate processing apparatus of claim 7, wherein:
the baffle is disposed around an outer circumference of the substrate support and partitions the process chamber into a processing space and an exhaust space, wherein the processing space processes the substrate with the process gas and the exhaust space discharges the process gas.

13. The substrate processing apparatus of claim 12, further comprising:
a pump configured to discharge the process gas from the process chamber to an outside of the process chamber through the exhaust space.

14. The substrate processing apparatus of claim 1, wherein the substrate support further comprises:
a pedestal detachably coupled to the plurality of support members on a first side of the pedestal;
a support shaft connected to a second side opposite to the first side of the pedestal; and
a driving device connected to the support shaft to rotatably drive the pedestal, wherein the driving device is configured to adjust a rotational speed of the pedestal.

15. A substrate processing apparatus, comprising:
a process chamber;
a gas supply unit configured to supply a process gas into the process chamber;
a heating unit configured to supply heat into the process chamber;
a pedestal disposed in the process chamber;
a baffle disposed around the pedestal to partition the process chamber into a processing space and an exhaust space; and
a plurality of support members detachably coupled to the pedestal in a first direction substantially perpendicular to an upper surface of the pedestal, and configured to support a substrate,
wherein the baffle includes an exhaust hole configured to discharge the process gas from the processing space to the exhaust space.

16. The substrate processing apparatus of claim 15, wherein:
the exhaust hole is formed on at least a portion of the baffle, and
the exhaust hole has a cross-section of a circular or polygonal shape.

17. The substrate processing apparatus of claim 15, wherein:
the exhaust hole has a width of a first length measured in a direction substantially parallel to the upper surface of the baffle and a height of a second length measured in a direction substantially perpendicular to the upper surface of the baffle, and
the first length is less than or equal to the second length and is equal to or less than one-fourth of a wavelength of microwaves supplied from the heating unit.

18. The substrate processing apparatus of claim 15, wherein the plurality of support members further comprises:
a first support member coupled to a first position on the pedestal;
a second support member coupled to a second position on the pedestal, where the second position is spaced apart from the first position in a second direction perpendicular to the first direction; and
a third support member coupled to a third position on the pedestal between the first position and the second position.

19. The substrate processing apparatus of claim 15, wherein each of the plurality of support members further comprises:
a plurality of support slots formed in each of the plurality of support members to support a substrate, wherein each of the plurality of support slots are spaced apart at a predetermined gap along the first direction.

20. A substrate processing apparatus, comprising:
a process chamber;
a gas supply unit configured to supply a process gas into the process chamber;
a heating unit configured to supply heat into the process chamber;
a pedestal connected to a support shaft disposed in the process chamber;
a driving device connected to the support shaft and rotatably driving the pedestal;
a baffle disposed around an outer circumference of the pedestal at a same level as the pedestal to partition the process chamber into a processing space and an exhaust space;
a pump configured to discharge the process gas from the processing space to outside of the process chamber through the exhaust space;
a first support member disposed at a first position on the pedestal in a first direction to support a first portion of a substrate, wherein the first direction is substantially perpendicular to an upper surface of the pedestal;
a second support member disposed at a second position on the pedestal, wherein the second position is spaced apart from the first position in a second direction perpendicular to the first direction to support a second portion of the substrate; and
a third support member disposed at a third position on the pedestal, wherein the third position is between the first position and the second position, wherein each of the first support member, the second support member, and the third support member includes a body part extending in the first direction, a plurality of support slots formed in the body part to support the substrate, and a coupling part configured to couple one end of the body part to an insertion hole of the pedestal, and
wherein the baffle includes an exhaust hole configured to discharge the process gas from the processing space to the exhaust space.
